(19) United States
(12) Patent Application Publication
(10) Pub. No.: US 2007/0246701 A1
(43) Pub. Date: Oct. 25, 2007

(54) Generating Multiple Bandgaps Using Multiple Epitaxial Layers

(75) Inventors: Dan Andreyevitch Yanson, Glasgow (GB); Gianluca Bacchin, Glasgow (GB); Olek Peter Kowalski, Paisley (GB); Stewart Duncan McDougall, Hazelbank Lanark (GB)

Correspondence Address: MOMKUS MCCLUSKEY MONROE MARSH & SPYRATOS, LLC, 3051 OAK GROVE ROAD, SUITE 220, DOWNERS GROVE, IL, 60515-1181, US

(73) Assignee: INTENSE LIMITED, Glasgow (GB)

(21) Appl. No.: 10/596,726

(22) PCT Filed: Dec. 24, 2004
(86) PCT No.: PCT/GB04/05452

§ 371 Date: Jun. 22, 2006

(30) Foreign Application Priority Data
Dec. 24, 2003 (GB) 0329915.3

(51) Int. Cl. H01L 29/06; H01L 21/00

(52) U.S. Cl. 257/15; 438/46; 438/483; 438/45; 257/22

(57) ABSTRACT

A quantum well intermixing (QWI) technique for modifying an energy bandgap during the formation of optical semi-conductor devices enables spatial control of the QWI process so as to achieve differing bandgap shifts across a wafer, device or substrate surface. The method includes: forming a substrate comprising one or more core layers defining at least one quantum well; depositing a succession of intermixing barrier layers over the quantum well, each successive intermixing barrier layer being formed of a semiconductor material and having a different etch characteristic than an immediately preceding barrier layer; etching away different numbers of the successive barrier layers in different regions of the substrate so as to provide different total thicknesses of barrier layer in different regions of the substrate; and applying an intermixing agent to the surface of the substrate such that the degree of intermixing the quantum well region varies as a function of the total thickness of barrier layer, thereby different bandgaps in the quantum well in each of the respective regions.

The present invention relates to quantum well intermixing (QWI) techniques suitable for modifying an energy bandgap during the formation of optical semiconductor devices. In particular, the invention relates to QWI techniques in which spatial control of the QWI process can be effected so as to achieve differing bandgap shifts across a wafer, device or substrate surface.

A vast body of research exists in the field of QWI. The QWI process consists in the selective disordering of the composition of the thin layers that form quantum wells, which results in a change of energy levels within each well causing the energy bandgap to shift. This allows one to alter the emission and absorption wavelengths of the intermixed material.

A variety of QWI techniques have been developed including: impurity-induced, impurity-free (dielectric cap), implantation-induced and laser-induced methods. QWI has been demonstrated in a range of material systems, including GaAs/AlGaAs and InP/(Al)InGaAs(P).

Much effort recorded in the prior art (prior art references are given in the Annex to this description, as referred to in square parentheses) has been directed to achieving a dual-bandgap process,—where the emphasis is on obtaining a large differential shift between areas of reduced shift (nominally the as-grown bandgap) and intermixed areas. Various techniques have been proposed to enhance control over bandgap shifts, e.g. varying the material [1, 2], deposition conditions [3, 4], stoichiometry [5], size [6] and thickness [7-9] of the dielectric cap in inpurity-free processes; ion irradiation dose [8, 10], laser exposure [11-14], surface coverage/resolution effects [15], and, most commonly, anneal temperature and duration in almost all of the above reports. Not all of these approaches, however, can be used to create multiple bandgap shifts on a single wafer—by temperature adjustment alone one cannot obtain more than one shift.

Most generally, multiple bandgaps can be created using a core dual-b andgap process with one of the following approaches:
1. Repeated [10, 15-21]/variable dose [12-14] exposure-anneal combinations;
2. Choice of dielectric caps of different material [2-5] and interface effects [1, 22-24];
3. QWI barrier masks [7, 9, 25, 26] and caps of varying thickness [7, 8]; and
4. Spatial/resolution effects [6, 15]

Despite the abundance of QWI techniques, there is a scarcity of prior art where these techniques could be used in a controlled manner to define multiple bandgap shifts on a common substrate.

A first prior art approach comprises various techniques where the rate of intermixing is controlled via the thickness of a barrier between the material being intermixed and the intermixing agent. The barrier may take the form of a mask or a backspace layer. The intermixing agent may be in the form of a dielectric cap containing an impurity source, or an ion beam directed at the material being intermixed.

These techniques are typified in the general approach marked as 3 above, which places a common requirement for highly accurate controllability of the barrier thickness and its composition in order to achieve target bandgaps.

A second prior art approach exemplified in [26] proposes that a stack of alternating layers of two different materials that can be selectively etched is first deposited on the sample. Selective etching is then performed to remove a given number of layers from the stack in various regions of the sample. Ion implantation, followed by a high-temperature anneal, is then used to induce intermixing, with regions capped by a different number of layers experiencing different bandgap shifts. Reference [26] proposes deposition of metal layers by evaporation or sputter deposition to form the stack of alternating layers. In particular, a copper and titanium alternating layer system is recommended. A chromium and silicon system described is reported to result in significant problems in silicide formation at the interface between the two materials, which silicide inhibited etching of the chromium layers.

Selective etching of alternate InP/InGaAs semiconductor layers has been reported in [28], for the purpose of precision depth control in the fabrication of a variable-width core waveguide laser. This technique, often referred to as stepped, or staircase etching, is employed for the definition of spot-size converters, mode expanders and tapered waveguides [29]. No suggestion of use of these layers as a QWI barrier has been proposed.

The group of references [1, 2, 22-24] marked as 2 above, and patent [30], are related to the use of composition of a topmost semiconductor layer and that of the dielectric cap, to control the bandgap shift in underlying areas. However, there is no suggestion of stacking or etching these barrier layers.

It is an object of the present invention to provide an improved QWI process that is capable of providing multiple bandgap shifts on a single device substrate, using a stack of alternating semiconductor layers that can be selectively etched and which provide a varying thickness barrier between a material to be intermixed and an intermixing agent.

According to one aspect, the present invention provides a method for producing multiple quantum well intermixed (QWI) regions having different bandgaps on a single substrate, comprising the steps of:
forming a substrate comprising one or more core layers defining at least one quantum well;
depositing a succession of intermixing barrier layers over the quantum well, each successive intermixing barrier layer being formed of a semiconductor material and having a different etch characteristic than an immediately preceding barrier layer;
etching away different numbers of the successive barrier layers in different regions of the substrate so as to provide different total thicknesses of barrier layer in different regions of the substrate; and
applying an intermixing agent to the surface of the substrate such that the degree of intermixing in the quantum well region varies as a function of the total thickness of barrier layer, thereby forming different bandgaps in the quantum well in each of the respective regions.

According to another aspect, the present invention provides a semiconductor optical device manufactured using the process defined above.

According to another aspect, the present invention provides a wafer of epitaxially grown material comprising a mechanically supporting substrate, one or more layers defining a quantum well structure deposited thereon, and a succession of intermixing barrier layers formed over the quantum well structure, each successive intermixing barrier layer being formed of a semiconductor material having a different etch characteristic than an immediately preceding barrier layer so that each successive layer can act as an etch stop layer to an immediately preceding higher layer.

Embodiments of the present invention will now be described by way of example and with reference to the accompanying drawings in which:

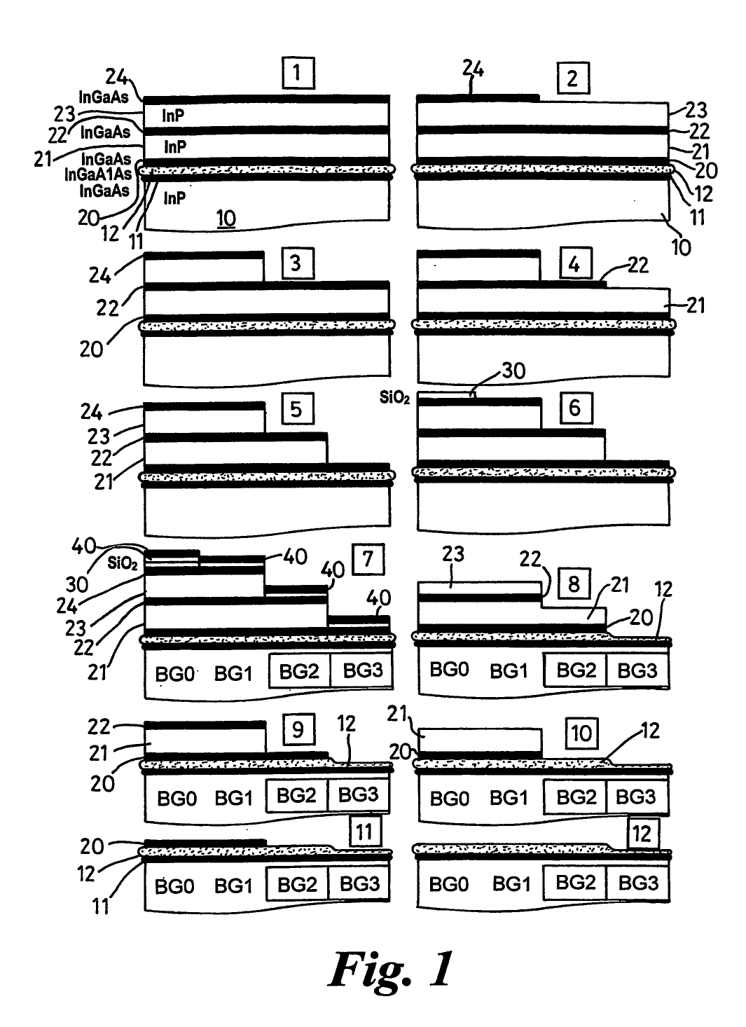

FIG. 1 is a schematic diagram of a device substrate during various stages of the QWI processing steps according to one embodiment of the present invention;

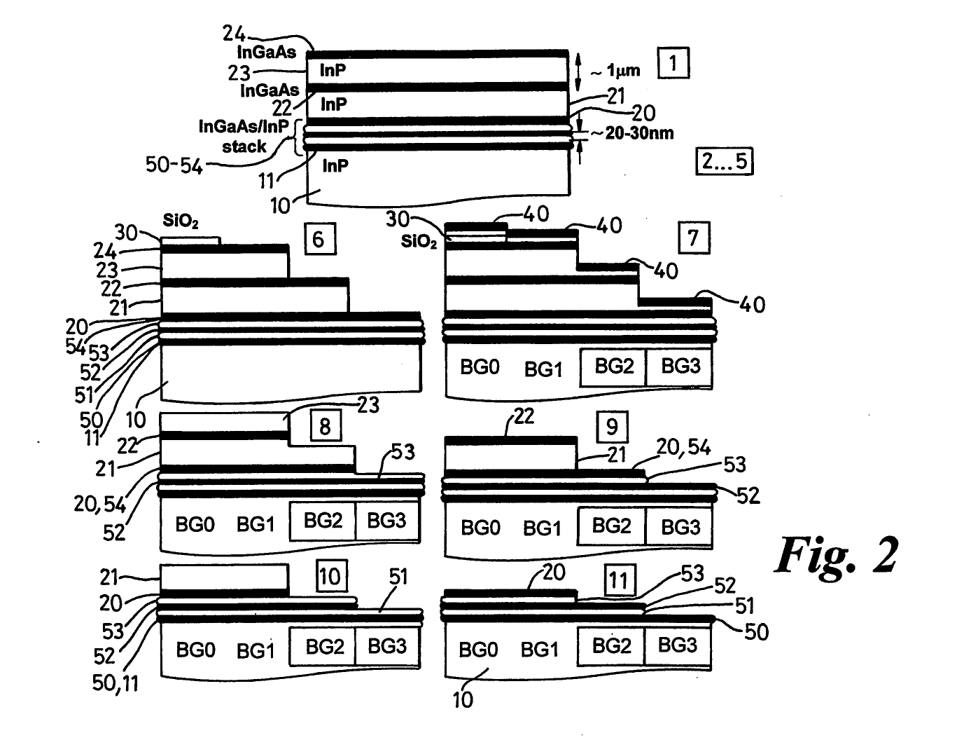

FIG. 2 is a schematic diagram of a device substrate during various stages of the QWI processing steps according to another embodiment of the present invention; and

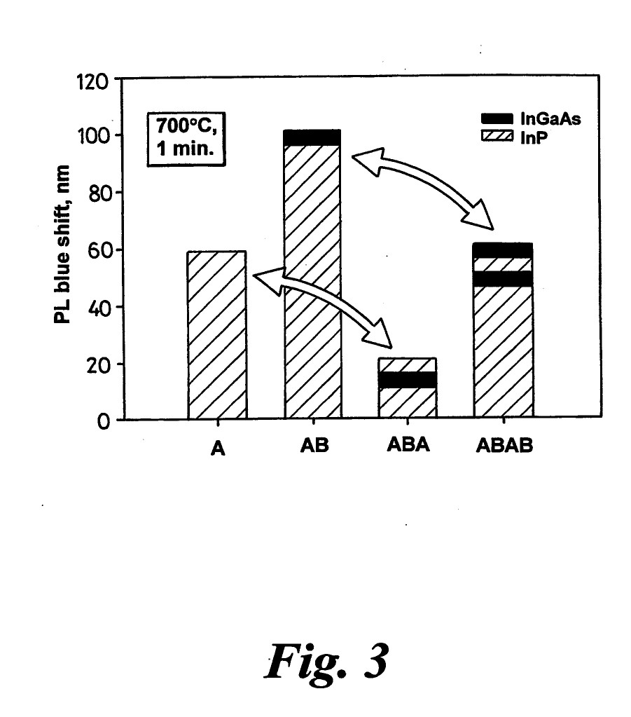

FIG. 3 is a graph showing bandgap shifts, represented by photoluminescence wavelength shift, effected in different regions of the substrate arising from the processing steps as applied to the structures of FIG. 1.

The process of the present invention allows multiple bandgaps to be defined in a controlled manner on the same wafer or substrate. The process is compatible, inter alia, with Al-quaternary InP material on a semi-insulating (SI) InP substrate, and thus can be used to fabricate high-frequency optoelectronic devices. This enables a plethora of component integration possibilities whereby active and passive components, each bandgap-tuned as required, can be fabricated on a common substrate as part of a photonic integrated circuit and/or a single integrated device. Examples include semiconductor optical amplifier (SOA)-preamplified modulators, photodetectors and switches, extended-cavity lasers, wavelength-detuned laser arrays, demultiplexors, etc.

For the avoidance of doubt, it is noted that throughout the present specification and particularly including the claims, for brevity and clarity the expression ‘substrate’ is used in a general sense to include the mechanically supporting and ‘original’ substrate and all further material layers in existence above that original substrate at the time of a subsequent process step. In other words, the expression ‘substrate’ is intended to cover the totality of previously processed material and layers to which a process or further process (e.g. layer deposition or thermal treatment) is to be applied. The original ‘raw material’ substrate will be referred to as the mechanically supporting substrate, although it will be understood that this too may change its physical and chemical characteristics during processing.

The process of the present invention allows multiple bandgaps to be defined in a controlled manner on the same wafer or substrate, by way of barrier thickness control through the sequential reduction of a stack of alternating ingrown epitaxial layers of different materials that are capable of being selectively etched over each other.

In a preferred embodiment, the process is implemented using custom-designed epitaxial wafer material having a sacrificial cap of alternating semiconductor layers. The number of layer pairs in the stack is two fewer than the total number of bandgaps required (i.e. including the as-grown one), whilst thicknesses and compositions of individual layers determine the shifts obtainable with stacked combinations of these layers. The composition of the topmost layer should, but does not have to, be the same as that of the bottommost layer.

FIG. 1 shows a process flow for intermixing Al-quaternary InP material to create four different bandgaps. The as-grown wafer structure includes an InP mechanically supporting substrate 10 which includes any cladding layers and one or more quantum well layers required to define and form an active waveguide core (hereinafter ‘core layers’). These layers are formed in the Al-quaternary materials in accordance with known techniques in the fabrication of optoelectronic devices, and will not be described further here.

Above the core layers are provided first and second cap layers, 11, 12 respectively in InGaAs and InGaAlAs, the preferred functions of which layers will be explained later.

Above these layers is provided a layered structure of intermixing barrier layers 20 to 24, comprising two repeats of an lnGaAs/InP layer pair 21, 22 and 23, 24 with an underlying lnGaAs layer 20. The wafer structure below the underlying barrier layer 20 depends on a choice of surface planarization techniques and ohmic contact requirements. These will be discussed later.

The alternating InGaAs and InP layers 20 to 24 are selected to provide differential etch properties, so that each layer can be etched using the lower layer as an effective etch stop. Selective wet etching using two different etch solutions is employed to etch one layer and stop on the other in an alternating fashion. For the specific embodiment described here, recommended etch recipes are:
Recipe 1: H₃PO₄:H₂O₂:H₂O (1:1:38); selectively etches InGaAs over InP
Recipe 2: HCl:H₂O (3:1); selectively etches InP over InGaAs.

In another example, the etch recipes may be:
Recipe 1: H₂SO₄:H₂O₂:H₂O (1:8:40); selectively etches InGaAs over InP
Recipe 2: HCl:H₃PO₄ (1:3); selectively etches InP over InGaAs.

In a first step, the substrate in FIG. 1-1 is photolithographically patterned to expose the surface in first and second regions corresponding to what will become the two largest bandgaps BG3 and BG2 (see FIGS. 1-7 to 1-12).

The topmost InGaAs layer 24 is then selectively etched using Recipe 1. The etch mask is removed leaving the substrate as shown in FIG. 1-2.

The underlying InP layer 23 is selectively etched using Recipe 2 to leave the substrate as shown in FIG. 1-3.

The substrate is then photolithographically patterned to expose the surface in the first regions corresponding to what will become the largest bandgap region (BG3—as seen in FIGS. 7 to 12). The InGaAs layer 22 is selectively etched using Recipe 1. The etch mask is removed leaving the substrate as shown in FIG. 1-4.

The underlying InP layer 21 is selectively etched using Recipe 2 to leave the substrate as shown in FIG. 1-5.

The substrate is then covered with a blanket layer of a QWI-suppressing material 30, such as PECVD silica. The substrate is then photolithographically patterned to protect the regions of suppressed or zero bandgap shift, shown as BGO in FIGS. 1-7 to 1-12 (i.e. the regions of 'as-grown bandgap). The silica 30 is then either dry-etched or wet-etched in the exposed areas (BG1, BG2, BG3) with an HF-based solution. The etch mask is removed leaving the substrate as shown in FIG. 1-6.

An intermixing agent, in the form of an intermixing cap or QWI-initiating layer 40, is deposited over the entire substrate surface to leave the substrate as shown in FIG. 1-7. The QWI-initiating layer 40 preferably consists of a sputter deposited layer of impurity and of silica. The impurity may be any one or more of sulphur, zinc, silicon, fluorine, copper, germanium, tin and selenium. The impurity may be incorporated within the silica layer as a doping impurity, or may formed as a separate impurity layer above, below or within the silica layer.

The substrate is then intermixed by way of a thermal process, preferably a high-temperature rapid thermal anneal. As shown in FIG. 1-7, the bandgaps BG1 to BG3 are created during this step. Bandgap BG0 corresponds to the as-grown (native) bandgap, which is preserved during the thermal process.

A typical rapid thermal anneal process may be performed between 600 and 700 degrees C. The temperature and duration of the rapid thermal anneal step may be selected in order to achieve the required bandgap shifts.

The QWI-initiating layer 40 is then removed, together with any silica layer 30, for example by wet etching using an HF-based etchant. The exposed upper layer 24 of InGaAs together with any exposed regions of impurity-rich barrier layer 20 are removed by dry etching and the topmost portion of the second cap layer 12 may also be removed by over-etching of the barrier layer 20. This leaves the substrate as shown in FIG. 1-8.

At this stage, the process for forming multiple quantum well intermixed regions having different bandgaps is complete. However, under many circumstances, it is desirable to planarize the surface of the substrate prior to further processing for device fabrication. For example, the formation of optical waveguides may require etching of the surface of the cap layers 11, 12 and it is desirable to perform these fabrication steps starting from a relatively planar substrate.

One presently preferred process for planarization is shown with reference to FIGS. 1-9 to 1-12. For best effect, the second cap layer 12 is chosen to have high etch resistance to both recipes 1 and 2, thereby acting as a common etch-stop layer. This way, the alternating wet etching routine can be continued after the bandgap shifting process until the remainder of the intermixing barrier layers 20 to 24 have been completely removed. The etching process will stop on the second cap layer 12. For this reason, the second cap layer, or common etch-stop layer 12 is preferably formed from InGaAlAs. InGaAlAs is known to have variable etchability in Recipes 1 and 2 depending on the mole fractions of the constituent elements and volume parts of the wet etch ingredients. By adjusting these parameters, the required selectivity can readily be achieved so that the InGaAlAs layer 12 is not attacked during etching of the lower InGaAs layer 20.

Other options include using different etch chemistries to etch the InP and InGaAs layers 20 to 24, which etches are selected not to etch the InGaAlAs common etch-stop layer 12. For example, citric acid-based solutions (C₆H₈O₇:H₂O₂) exhibit different etch selectivities for a range of volume part ratios [31].

In another alternative, instead of an InGaAlAs layer, one can employ an ultra-thin AlAs common etch stop layer 12 (several monolayers thick), which has been shown to be a reliable etch-stop layer in InP/InGaAs material systems [32].

Using a common etch-stop layer 12, the uppermost InP layer 23 is removed using etch Recipe 2, leaving the substrate as shown in FIG. 1-9. The uppermost InGaAs layer 22 is then removed using etch Recipe 1 to leave the substrate as shown in FIG. 1-10. The uppermost InP layer 21 is then removed using etch Recipe 2 to leave the substrate as shown in FIG. 1-11.

The remaining parts of the InGaAs layer 20 are then removed using etch Recipe 1, leaving the common etch-stop layer 12, as shown in FIG. 12 Finally, this common etch-stop layer 12 can then removed by either dry etching or appropriate wet-etching, leaving a standard InGaAs contact layer 11 as the uppermost layer of the substrate. The device fabrication cycle can then continue in a conventional known manner suitable for manufacture of desired optoelectronic devices.

In some circumstances, it may be desirable to avoid using a planarization etch-stop layer 12, for example, where this interferes with the migration of intermixing impurities into the main body of the substrate from the QWI-initiating layer 40. In these circumstances, an alternative planarization process may be used which makes use of a replica stack of InP/InGaAs layers 50 to 54, below the main InP/InGaAs layers 20 to 24, as shown in FIG. 2. This replica stack of layers 50 to 54 is identical in layer sequence and preferably identical in chemistry to the main stack of InP/InGaAs layers 20 to 24. However, in the replica stack, the layer thicknesses are much thinner, preferably to an extent that the existence of residual portions of the stack in various regions of the substrate will not cause difficulties in subsequent processes.

With reference to FIG. 2, the alternative planarization process is now described. The replica stack of layers 50 to 54 is shown in FIG. 2-1. Note that the uppermost InGaAs layer 54 of the replica stack is effectively the same layer as, or contiguous with, the lowermost InGaAs layer 20 of the main barrier layer stack. Similarly, the lowermost InGaAs layer 50 of the replica stack is effectively the same layer as, or contiguous with, the InGaAs cap layer 11 of the main body of the substrate.

The main barrier layers 20 to 25 are typically of the order of several hundred nanometers thick, or even up to 1 micron thick. The layer thickness of these barrier layers is determined by the requirements of the QWI process used, in that the individual layer thicknesses must be sufficient to suppress migration of impurities to the quantum well to the extent necessary to achieve the correct bandgap shifts. However, the replica stack layers 50 to 54 should consist only of thin etch-stop layers of the order of, typically, 20 to 30 nm thickness. As will become clear, the thickness of each of these layers should be sufficient to resist substantial overetching periods of the adjacent upper layer, but insufficiently thick to (a) cause planarity problems after the QWI process is completed, and (b) significantly reduce the local effectiveness of the QWI process.

The first processing stages are carried out in corresponding manner to those described with reference to FIGS. 1-1 to 1-6. Therefore, upon completion of the barrier layer processing steps shown with reference to FIGS. 1-1 to 1-6, applied to the substrate of FIG. 2-1, a corresponding result is shown in FIG. 2-6. (Corresponding FIGS. 2-2 to 2-5 are omitted for conciseness.)

An intermixing agent, in the form of an intermixing cap or QWI-initiating layer 40, is deposited over the entire substrate surface to leave the substrate as shown in FIG. 2-7. The QWI-initiating layer 40 preferably consists of a sputter-deposited layer of impurity and of silica as previously described.

The substrate is then intermixed by way of a thermal process, preferably a high-temperature rapid thermal anneal. As shown in FIG. 2-7, the bandgaps BG1 to BG3 are created during this step. Bandgap BG0 corresponds to the as-grown (native) bandgap.

The QWI-initiating layer 40 is then removed, together with any silica layer 30, for example by wet-etching using an HF-based etchant. The exposed upper barrier layer 24 of InGaAs together with any exposed regions of barrier layer 20 (replica layer 54) are removed by dry or wet etching. This leaves the substrate as shown in FIG. 2-8.

To planarize the surface, the barrier layer 23 is removed with an appropriate wet etch recipe which will also remove the thin replica layer 53. However, although the thin replica layer will be subject to a substantial overetch period sufficient to remove the thicker barrier layer 23, the etch-stop layer 52 will prevent further etching of the substrate in the BG3 region. The result is shown in FIG. 2-9. An appropriate etch recipe is then used to remove barrier layer 22 and, correspondingly, replica layer 52, the etch stopping on layers 21 and 51 to leave the substrate as shown in FIG. 2-10. Subsequently, an appropriate etch process removes layers 21 and 51 to leave the substrate as shown in FIG. 2-11.

Although some or all of the replica layers 50 to 54 are still present in certain regions of the substrate, because these replica layers are very thin (e.g. between one and two orders of magnitude thinner than the removed barrier layers 20 to 24), there is little difficulty with subsequent device processing steps. The resulting replica stack is preferably less than 100 nm thick in its highest regions. Such height non-uniformity across the sample surface is acceptable, especially if a further etch-stop process is used later in the processing, e.g. to define the etch depth of optical waveguides.

Other approaches may include the use of an extra-thick InP buffer layer 12′ (instead of cap layer 12, FIG. 1-1) as a buffer underneath the barrier layers 20 to 24. If the buffer layer 12′ is sufficiently thick so that some of it remains after the series of barrier definition etches, then the substrate can be planarized in a single extended wet etch step by reliance on the InGaAs cap layer 11 underneath the InP buffer.

It will be noted from FIGS. 1 and 2 that each separate bandgap shift region of the substrate (BG1 . . . BG3) is defined by a different number of barrier layer pairs (in the example, each pair comprising an InP layer and an InGaAs layer). In other words, region BG3 is protected by zero barrier layer pairs; region BG2 is protected by one barrier layer pair 21, 22; region BG1 is protected by two barrier layer pairs 21, 22, 23, 24; while region BG0 is protected by an additional QWI-suppression cap. However, it will be understood that the technique could be practised by each separate region BG0 . . . BG3 being protected with a respective number of single barrier layers, rather than barrier layer pairs. In this instance, each successive barrier layer must provide (i) the requisite increased resistance to bandgap shift in underlying areas during the QWI process; and (ii) the necessary etch stop chemistry for removal of the immediately higher barrier layer.

The bar chart of FIG. 3 shows the bandgap shifts observed experimentally in Al-quaternary MQW InP material intermixed using such a process. The barrier layer structure is represented with the following codes: “A” represents an InP layer, and “B” represents an InGaAs layer.

As is evident from FIG. 3, differential bandgap shifts can be obtained in three ways: (i) exploitation of the interface effect of the material of the topmost layer in contact with the QWI-initiating cap 40 (e.g., A vs. AB, AB vs. ABA, ABA vs. ABAB); (ii) the effect of the stack thickness for an identical topmost layer (A vs. ABA and AB vs. ABAB); and (iii) the number of interfaces and the sequence of layers within the barrier layer stack. Thus, it will be understood that the ‘resistance to bandgap shift’ afforded by a barrier layer 20 to 24 may be a function not only of the thickness of the barrier layer, but also of its interaction with the QWI-initiating cap (i.e. the surface interface effects at the boundary between the two materials, and also of the number of layer interfaces within the barrier layer stack (i.e. the interface effects at boundaries within the barrier layer stack). It is noted that the techniques of the invention described herein are compatible with exploitation of both interface effects and barrier thickness effects to control a degree of QWI that takes place. Interface effects are described in references [1, 2, 22-24] and patent [30].

The paired barrier layer approach (marked by arrows in FIG. 3, and as described in connection with FIGS. 1 and 2), offers substantial advantages in view of maintaining identical QWI-initiating layer/barrier layer interface effects. These interface effects can be very significant in some QWI processes.

The paired barrier layer technique avoids any difficulties which may otherwise be caused by the requirement to use an etch chemistry that allows selective etch of the QWI-initiating layer against both the first and second barrier layer material types. In other words, in using a paired barrier layer technique, the removal of the QWI-initiating layer 40 .(progressing from the substrate of FIG. 1-7 to the substrate of FIG. 1-8) requires an etch that stops against the same material type (layers 20, 22 and 24).

Conversely, if only a single extra barrier layer is used for each successive region BG3 to BG1, then the removal of the QWI-initiating layer 40 has to stop against two or more different types of material. Thus, the selectivity of the etch chemistry of the topmost barrier layer relative to that of the QWI-initiating cap may also be considered when selecting either the single barrier layers approach or the paired barrier layers approach.

It will be understood that the processes described above can be extended in principle to any number of different bandgaps.

Although the exemplary embodiments above have been described in connection with an impurity-based QWI-initiating layer, other types of QWI-initiating materials and techniques may be used to initiate, accelerate or promote the intermixing process. These include impurity-free dielectric caps, sputtered materials (e.g. silica), plasma/sputter damage and some of the techniques outlined in the review of the prior art above. It is noted that the QWI-initiating layer processes described in connection with FIGS. 1 and 2 would be incompatible with the barrier layers proposed in reference [26]. QWI intermixing can also be induced by ion implantation.

In a general sense, it is noted that the QWI-initiating layer, or ion implantation, effectively provide a means for applying an intermixing agent (e.g. impurity) to the surface of the substrate. The expression ‘surface of the substrate’ is intended to encompass ion implantation where substantial quantities of the introduced agent are actually driven past the surface.

In preferred embodiments, the application of the intermixing agent includes an intermixing agent activation step, such as the high temperature rapid thermal anneal process described above. Some QWI processes, for example photo-absorption-induced disordering, may require no activation step at all.

Although the exemplary embodiments above have been described in connection with a QWI-inhibiting layer of PECVD silica layer, other types of QWI-inhibiting materials may be used to inhibit, suppress or otherwise retard the intermixing process. These include spin-on glass, sputtered silica etc.

In practice, the QWI-inhibiting layer 30 might not be required at all in certain circumstances. In a first example, if the cumulative thickness of barrier layers 20 to 24 is sufficient to completely suppress QWI in the thickest region BG0, then the native as-grown bandgap BG0 will be retained in those areas This technique could be particularly applicable where implantation is used for application of the QWI agent. In a second example, it might not be necessary to retain the native as-grown bandgap, i.e. the region BG0 might also be intentionally bandgap shifted. In a third example, where the presence of, for example, the InGaAs layer 24 at an interface with the QWI-initiating material is important to enhance migration of the QWI agent into the substrate, omission (i.e. removal) of this layer in the BG0 region may be sufficient to substantially depress migration of the QWI agent such that the remaining thickness of barrier layers 20 to 23 are themselves sufficient to effectively prevent QWI in region BG0. In this case, rather than depositing layer 30, the upper barrier layer might actually be removed in the BG0 regions. In a fourth example, the removal of QWI-initiating material in the BG0 region prior to the activation step (e.g., rapid thermal anneal) may prove sufficient to suppress any bandgap shift in that region. The QWI-initiating cap in the BG0 region may be removed either by etching or lit-off using photolithography. In this case, the anneal conditions used to induce bandgap shifts in areas BG1-BG3 covered by the QWI-initiating cap must not affect the native bandgap in the uncapped region BG0.

Embodiments of the invention offer a number of advantages. It is possible to create a large number of bandgap shifts of arbitrary magnitude and these can readily be altered. Multiple bandgap shifts can be achieved with only a single intermixing step, i.e. a single application/activation of a QWI-initiating agent. Superior barrier layer thickness and composition control can be achieved by virtue of the use of epitaxially grown barrier layers, preferably using the same equipment as used for formation of the substrate quantum well structures.

Preferably, the barrier layers are formed in a continuous process sequence with the epitaxial growth of the underlying substrate quantum well structures (i.e. without removal of the wafer substrates from the vacuum deposition environment), guaranteeing high purity and low contamination. This is a substantial improvement over the provision of separately deposited) (evaporated or sputtered) metal barrier layers as proposed in reference [26]. Epitaxial growth of the barrier layers as described here ensures extremely good spatial uniformity of the layers, compositional control and near-atomic scale precision which ensure superior etch rate control and control of migration of the QWI initiating agent during the application/activation step.

Furthermore, the process is suitable for large-scale production because the barrier layer thicknesses and compositions can be incorporated into the as-grown wafers for later application of the QWI processes. No post-growth barrier layer deposition is necessary.

Further advantages can be realised in that the process described herein can be made fully compatible with a wide range of different materials systems including Al-quaternary InP material systems on a semi-insulating InP substrate. Planarization of the substrate after QWI processing can be effected without any further photolithography steps which reduces cost and potential yield losses.

Other embodiments are intentionally within the scope of the accompanying claims.

### ANNEX 1: REFERENCES

[1] Y. Hee Taek, et al, “Effect of dielectric-semiconductor capping layer combination on the dielectric cap quantum well disordering of InGaAs/InGaAsP quantum well structure”, Technical Digest. CLEO/Pacific Rim '99. Pacific Rim Conference on Lasers and Electro Optics Cat. No. 99TH8464., vol. 3, pp. 3, 1999.
[2] Y. Jae Su et al, “Effects of In/sub 0.53/Ga/sub 0.47/As cap layer and stoichiometry of dielectric capping layers on impurity-free vacancy disordering of In/sub 0.53/Ga/sub 0.47/As/InP multiquantum well structures”, J. Appl. Phys, vol. 88, pp. 5720-3, 2000.
[3] W. J. Choi, et al, “Control of the intermixing of InGaAs/InGaAsP quantum well in impurity free vacancy disordering by changing NH/sub 3/flow rate during the growth of SiN/sub x/capping layer”, Infrared Applications of Semiconductors III. Symposium Materials Research Society Symposium Proceedings, vol. 607, pp. 515-18, 2000.
[4] Y. Jae Su, et al, “Influence of dielectric deposition parameters on the In/sub 0.2/Ga/sub 0.8/As/GaAs quantum well intermixlng by impurity-free vacancy disordering”, J. Appl Phys, vol. 92, pp. 1386-90, 2002.
[5] Y. Jae Su, et al, “Dependence of band gap energy shift of In/sub 0.2/Ga/sub 0.8/As/GaAs multiple quantum well structures by impurity-free vacancy disordering on stoichiometry of SiO/sub x/and SW/sub x/capping layers”, J. Appl. Phys, vol. 91, pp. 4256-60, 2002.
[6] W. J. Choi, et al, “Multiple wavelength lasers defined by stripe-width using one step impurity free quantum well intermixing technique”, Proceedings of the SPIE International Soc. for Optical Engineering, vol. 3628, pp. 267-74, 1999.
[7] H. S. Lim, et al, “A novel fabrication technique for multiple-wavelength photonic-integrated devices in InGaAs-InGaAsP laser heterostructures”, IEEE Photonics Technology Letters. May, vol. 14, pp. 594-6, 2002.
[8] X. F. Liu, et al, “Control of multiple bandgap shifts in InGaAs-AlInGaAs multiple-quantum-well material using different thicknesses of PECVD SiO/sub 2/protection layers”, IEEE Photonics Technology Letters, vol. 12, pp. 1141-3, 2000.
[9] S. L. Ng, et al, “A low-cost solution in generating multiple-bandgaps for 1.55 mu m optical fibre communications”, Leos, pp. 626-7, 2001.
[10] P. G. Piva, et al, “Enhanced compositional disordering of quantum wells in GaAs/AlGaAs and InGaAs/GaAs using focused Ga/sup+/ion beams”, Appl. Phys. Letters, vol. 65, pp. 621-3, 1994.
[11] J. J. Dubowski, et al, “Monolithic multiple wavelength ridge waveguide laser array fabricated by Nd:YAG laser-induced quantum well intermixing”, J Vacuum Science & Technology A Vacuum, Surfaces, and Films. July, vol. 20, pp. 1426-9, 2002.
[12] T. K Ong, et al, “Fabrication of multiple-wavelength lasers in InGaAs-InGaAsP structures using direct laser writing”, IEEE Photonics Technology Letters. Nov., vol. 13, pp. 1161-3, 2001.
[13] T. K Ong, et al, “Wavelength tuning in InGaAs/InGaAsP quantum well lasers using pulsed-photoabsorption-induced disordering”, Appl. Phys. Letters, vol. 78, pp. 2637-9, 2001.
[14] T. K Sudoh, et al, “Wavelength trimming of distributed-feedback lasers by photo-absorption-induced disordering”, Conference Proceedings. LEOS '96 9^{th} Annual Meeting. IEEE Lasers and Electro Optics Soc, pp. 419-20, 1996.
[15] B. S. Ooi, et al, “Selective Quantum-Well Intermixing in GaAs-AlGaAs Structures Using Impurity-Free Vacancy Diffusion”, IEEE J. Q. Elect., vol. 33, pp. 1784-1793, 1997.
[16] T. Miyazawa, et al, “Compositional disordering of In/sub 0.53/Ga/sub 0.47/As/In/sub 0.52/Al/sub 0.48/As multiquantum well structures by repetitive rapid thermal annealing”, Japanese J. of Appl Phys, Part, vol. 28, pp. L730-3, 1989.
[17] B. S. Ooi, et al, “Plasma-based integration process for photonic integrated circuits”, CLEO '195. Summaries of Papers Presented at the Conference on Lasers and Electro Optics IEEE Cat. No. 95CH35800., vol. 224, pp. 224, 1995.
[18] P. G. Piva, et al, “Bandgap tuning of semiconductor quantum well structures using ion implantation”, Superlattices and Microstructures, vol. 15, pp. 385-9, 1994.
[19] P. J. Poole, et al, “The enhancement of quantum well intermixing through repeated ion implantation”, Semiconductor Science and Technology. Nov., vol. 9, pp. 2134-7, 1994.
[20] L. Fu, et al, “Tuning of detection wavelength of quantum-well infrared photodetectors by quantum-well intermixing”, Infrared Physics & Technology, vol. 42, pp. 171-175, 2001.
[21] A. G. Steele, et al, “Postgrowth tuning of quantum-well infrared detectors by rapid thermal annealing”, in Selected Papers on Quantum Well Intermixing for Photonics, SPIE Milestone Series MS145, E. H. Li, Ed., 1998, pp. 497-499.
[22] K Hyun Soo, et al, “Quantum well intermixing of In/sub 1-x/Ga/sub x/As/InP and In/sub 1-x/Ga/sub x/As/In/sub 1-x/Ga/sub x/As/sub 1-y/P/sub y/multiple-quantum-well structures by using the impurity-free vacancy diffusion technique”, Semiconductor Science and Technology. Oct., vol. 15, pp. 1005-9, 2000.
[23] H. T. Yi, et al, “Effect of dielectric and semiconductor cap layer combinations in impurity free vacancy disordering of an InGaAs/InGaAsP single quantum well structure”, Sae Mulli. Sept., vol. 41, pp. 193-8, 2000.
[24] H. T. Yi, et al, “Dependence of quantum well disordering of InGaAs/InGaAsP quantum well structures on the various combinations of semiconductor-dielectric capping layers”, J. Materials Science Letters, vol. 19, pp. 835-6, 2000.
[25] S. L. Ng, et al, “Polarisation-dependent performance of multiple wavelength electro-absorption intensity modulator arrays on a single InGaAs/InGaAsP chip”, Leos, pp. 40-1, 2001.
[26] V. Aimez, et al, “High precision metal masking for multiple wavelength laser diode fabrication using single step ion implantation induced quantum well intermixing”, Proceedings of the SPIE The International Society for Optical Engineering, vol. 4087, pp. 607-15, 2000.
[27] M. Paquette, et al, “Blueshifting of InGaAsP/InP laser diodes by low-energy ion implantation”, Appl. Phys Letters, vol. 71, pp. 3749-51, 1997.
[28] H. H. Tan, et al, “Improved intermixing in GaAs/AlGaAs quantum well structures through repeated implant-anneal sequence”, presented at Conference on Optoelectronic and Microelectronic Materials and Devices Proceedings, Pert, Dec. 14-16, 1998.
[29] L. A. Coldren, “ECE Technical Report 03-02:2002 Reprints of Professor Larry A. Coldren and Collaborators”, Department of Electrical & Computer Engineering, University of California, Santa Barbara 2002.
[30] L. A. Coldren, “Publication List, section 1B “Quantum-Well-Intermixing for Photonic ICs”, http://www.ece.ucsb.edu/Faculty/Coldren/reprints/2002Reprint/2002Listof Pubs.pdf ed: Department of Electrical & Computer Engineering, University of California, Santa Barbara, 2003.

1. A method for producing multiple quantum well intermixed (QWI) regions having different bandgaps on a single substrate, comprising the steps of:
forming a substrate comprising one or more core layers defining at least one quantum well;
depositing a succession of intermixing barrier layers over the quantum well, each successive intermixing barrier layer being formed of a semiconductor material and having a different etch characteristic than an immediately preceding barrier layer;
etching away different numbers of the successive barrier layers in different regions of the substrate so as to provide different total thicknesses of barrier layer in different regions of the substrate; and
applying an intermixing agent to the surface of the substrate such that the degree of intermixing in the quantum well region varies as a function of the total thickness of barrier layer, thereby forming different bandgaps in the quantum well in each of the respective regions.

2. The method of claim 1 in which the step of depositing the intermixing barrier layers comprises epitaxial growth.

3. The method of claim 1 in which the intermixing barrier layers each comprise substantially single crystal semiconductor layers.

4. The method of claim 1 in which the steps of forming the substrate and depositing the intermixing barrier layers are carried out in the same epitaxial growth equipment.

5. The method of claim 1 in which the step of applying an intermixing agent to the surface of the substrate comprises bombarding the substrate with high energy ions in an ion implantation process.

6. The method of claim 1 in which the step of applying an intermixing agent to the surface of the substrate comprises depositing a QWI cap layer onto the substrate, the QWI cap layer initiating or promoting intermixing.

7. The method of any preceding claim claim 1 further including the step of activating the intermixing agent.

8. The method of claim 7 in which the step of activating the intermixing agent comprises thermally processing the substrate after delivering the intermixing agent to the substrate.

9. The method of claim 1 in which the barrier layers alternate between two different material types.

10. The method of claim 1 in which the barrier layers are grouped in pairs, each of the respective regions having a different number of pairs of barrier layers.

11. The method of claim 1 in which the quantum well region is formed from an aluminium quaternary indium phosphide material.

12. The method of claim 1 in which the intermixing barrier layers include successive layers of indium phosphide (InP) and indium gallium arsenide (InGaAs).

13. The method of claim 12 in which the etching step comprises etching the InGaAs layers in H₃PO₄:H₂O₂:H₂O and etching the InP layers in HCl:H₂O.

14. The method of claim 12 in which the etching step comprises etching the InGaAs layers in H₂SO₄:H₂O₂:H₂O and etching the InP layers in HCl:H₃PO₄.

15. The method of claim 1 in which the quantum well is formed from an aluminium ternary gallium arsenide material.

16. The method of claim 1 in which the intermixing barrier layers include successive layers of gallium arsenide (GaAs), aluminium gallium arsenide (AlGaAs) or aluminium arsenide (AlAs).

17. The method of claim 16 in which the etching step comprises etching the GaAs layers in H₂SO₄:H₂O₂:H₂O and etching the AlGaAs/AlAs layers in a buffered HF solution.

18. The method of claim 1 further comprising the step of planarizing the substrate after the applying the intermixing agent.

19. The method of claim 18 in which the planarizing step comprises removing one or more of the intermixing barrier layers from the surface of the substrate.

20. The method of claim 19 in which the planarizing step comprises removing all of the intermixing barrier layers from the surface of the substrate.

21. The method of claim 1 in which the step of depositing the succession of intermixing barrier layers comprises:
depositing a first intermixing barrier layer onto the substrate over said quantum well region, the first barrier layer being formed of a semiconductor material having a first etch characteristic;
depositing a second intermixing barrier layer onto the substrate over said first barrier layer, the second barrier layer being formed of a semiconductor material having a second etch characteristic; and
etching away the first and second barrier layers in first regions of the substrate and etching away the second barrier layer in second regions of the substrate and leaving the first and second barrier layers in other regions of the substrate;
such that after applying the intermixing agent to the surface of the substrate, different bandgaps in the quantum well region are respectively formed in each of the first regions, the second regions and the other regions.

22. The method of claim 21 in which the step of depositing further includes depositing a third intermixing barrier layer onto the substrate prior to depositing the first and second barrier layers, the third barrier layer being formed of a semiconductor material having a third etch characteristic; and
in which the etching step includes etching away the first, second and third barrier layers in third regions of the substrate;
such that after applying the intermixing agent to the surface of the substrate, different bandgaps in the quantum well region are respectively formed in each of the first regions, the second regions, the third regions and the other regions.

23. The method of claim 22 in which the third etch characteristic is the same as the second etch characteristic.

24. The method of claim 1 in which the step of depositing the succession of intermixing barrier layers comprises:
depositing a first and second intermixing barrier layers onto the substrate over said quantum well region, the first and second barrier layers being formed of semiconductor material and respectively having first and second etch characteristics;
depositing a third and fourth intermixing barrier layers onto the substrate over said first and second barrier layers, the third and fourth barrier layers being formed of semiconductor material and respectively having third and fourth etch characteristics;
etching away the first, second, third and fourth barrier layers in first regions of the substrate and etching away the third and fourth barrier layers in second regions of the substrate and leaving the first, second, third and fourth barrier layers in other regions of the substrate;
such that after applying the intermixing agent to the surface of the substrate, different bandgaps in the quantum well region are respectively formed in the first regions, the second regions and the other regions.

25. The method of claim 6 in which the QWI cap layer comprises an impurity rich material.

26. The method of claim 25 in which the impurity comprises one or more of sulphur, zinc, silicon, fluorine, copper, germanium, tin and selenium.

27. The method of claim 25 or claim 26 in which the impurity-rich material comprises silica doped with one or more of the impurities sulphur, zinc, silicon, fluorine, copper, germanium, tin and selenium.

28. The method of claim 6 in which the QWI cap layer is sputter deposited.

29. The method of claim 18 further including the steps of:
depositing a succession of planarization layers beneath the succession of intermixing barrier layers, the succession of planarization layers identical in number of layers and layer materials to the first succession of barrier layers, but having a total thickness substantially less than the total thickness of the first succession of intermixing barrier layers;
planarizing the substrate by successively removing intermixing barrier layers and corresponding planarization layers in a series of selective etches.

30. A wafer of epitaxially grown material comprising a mechanically supporting substrate, one or more layers defining a quantum well structure deposited thereon, and a succession of intermixing barrier layers formed over the quantum well structure, each successive intermixing barrier layer being formed of a semiconductor material having a different etch characteristic than an immediately preceding barrier layer so that each successive layer can act as an etch stop layer to an immediately preceding higher layer.

31. The wafer of claim 30 in which the intermixing barrier layers are alternating in etch characteristic.

32. The wafer of claim 30 in which the intermixing barrier layers are arranged in adjacent pairs, at least one of the barrier layers of each pair providing a substantial resistance to migration of QWI-initiating agent.

33. The wafer of claim 30 including a first succession of barrier layers having a first total thickness, and a second succession of planarization layers identical in number of layers and layer materials to the first succession of barrier layers, but having a second total thickness substantially less than the first total thickness.

34. The wafer of claim 33 in which the second total thickness is more than an order of magnitude less than the first total thickness.

35. (canceled)

36. (canceled)
